(19) United States
(12) Patent Application Publication
(10) Pub. No.: US 2017/0124979 A1
(43) Pub. Date: May 4, 2017

(54) DISPLAY PANEL, MANUFACTURING METHOD THEREOF, AND DRIVING METHOD THEREOF

(71) Applicant: Novatek Microelectronics Corp., Hsinchu (TW)

(72) Inventors: Ju-Lin Huang, Hsinchu County (TW); Jhih-Siou Cheng, New Taipei City (TW)

(21) Appl. No.: 14/925,953

(22) Filed: Oct. 28, 2015

(51) Int. Cl. G09G 5/00; G02F 1/133; G02F 1/1362; H01L 27/12

(52) U.S. Cl. CPC G09G 5/003; H01L 27/124; H01L 27/1255; H01L 27/1259; G02F 1/13306; G02F 1/136286

(57) ABSTRACT

A display panel, a manufacturing method thereof, and a driving method thereof are provided. The display panel includes at least one source line and a plurality of pixel circuits. The source terminal of each of the pixel circuits is coupled to the source line. The pixel circuits include a near pixel circuit and a far pixel circuit. The distance from the near pixel circuit to a source driver is less than the distance from the far pixel circuit to the source driver. The input impedance (in turn-on state) of the source terminal of the near pixel circuit is greater than the input impedance (in turn-on state) of the source terminal of the far pixel circuit, so as to compensate the source line impedance difference at different locations of the same source line.

### BACKGROUND OF THE INVENTION

Field of the Invention

The invention relates to a display apparatus, and more particularly, to a display panel, a manufacturing method thereof, and a driving method thereof.

Description of Related Art

A display panel generally includes a plurality of pixel circuits. The pixel circuits have the same layout structure, and therefore the electrical characteristics thereof are similar to one another. For instance, the source terminals of the pixel circuits at different locations may have the same input impedance. A source driver can transmit different pixel voltages to the source terminals of the pixel circuits via different source lines. A gate driver can transmit different levels of scanning pulses to the gate terminals of the pixel circuits via different gate lines, so as to turn on the pixel circuits at different times. The high-voltage levels (gate high-voltages) of the scanning pulses are the same as one another. In accordance with the scan sequence of the gate driver, the pixel voltages can be written to the corresponding pixel circuits to display an image.

The source lines generally have impedance (resistive impedance and capacitive impedance). The greater the size of the display panel (longer source lines), the greater the impedance of the source lines. Moreover, the greater the density/resolution of the display panel (thinner source lines), the greater the impedance of the source lines. Due to the impedance of the source lines, different pixel circuits connected to the same source terminal have different time constants. The time constant of the pixel circuit far from the source driver is greater than the time constant of the pixel circuit near the source driver. A greater time constant represents shorter charging time of the pixel circuits. Under the development trend of greater size, increasing resolution, and higher frequencies of the display panel, time constant difference caused by the impedance of the source lines becomes significant. Time constant difference (charging time difference) may cause display abnormality.

### SUMMARY OF THE INVENTION

The invention provides a display panel, a manufacturing method thereof, and a driving method thereof capable of compensating a source line impedance difference between different pixel circuits at different locations of the same source line.

A display panel of an embodiment of the invention includes at least one source line and a plurality of pixel circuits. The source terminal of each of the pixel circuits is coupled to the source line. The pixel circuits include a near pixel circuit and a far pixel circuit. The distance from the near pixel circuit to a source driver is less than the distance from the far pixel circuit to the source driver. The input impedance of the source terminal of the near pixel circuit in a turn-on state is greater than the input impedance of the source terminal of the far pixel circuit in the turn-on state.

A manufacturing method of a display panel of an embodiment of the invention includes: providing at least one source line to the display panel; and providing a plurality of pixel circuits to the display panel, wherein the source terminal of each of the pixel circuits is coupled to the source line, the pixel circuits include a near pixel circuit and a far pixel circuit, and the distance from the near pixel circuit to a source driver is less than the distance from the far pixel circuit to the source driver; and adjusting the input impedance of the source terminal of at least one of the pixel circuits, such that the input impedance of the source terminal of the near pixel circuit in a turn-on state is greater than the input impedance of the source terminal of the far pixel circuit in the turn-on state.

An embodiment of the invention provides a driving method of a display panel. The display panel includes at least one source line, a first gate line, a second gate line, and a plurality of pixel circuits. The source terminal of each of the pixel circuits is coupled to the source line. The pixel circuits include a near pixel circuit and a far pixel circuit. The distance from the near pixel circuit to a source driver is less than the distance from the far pixel circuit to the source driver. The gate terminal of the near pixel circuit is electrically connected to the first gate line. The gate terminal of the far pixel circuit is electrically connected to the second gate line. The driving method includes: providing a first gate high-voltage to the first gate line to turn on the near pixel circuit; and providing a second gate high-voltage to the second gate line to turn on the far pixel circuit, wherein the first gate high-voltage of the first gate line is less than the second gate high-voltage of the second gate line, such that the input impedance of the source terminal of the near pixel circuit in a turn-on state is greater than the input impedance of the source terminal of the far pixel circuit in the turn-on state.

Based on the above, the display panel, the manufacturing method thereof, and the driving method thereof of an embodiment of the invention can allow the source terminals of different pixel circuits at different locations of the same source line to have different turn-on impedances (input impedance in turn-on state), so as to compensate the source line impedance difference at different locations of the same source line.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates circuit block schematic of a display apparatus according to an embodiment of the invention.

FIG. 2 illustrates an equivalent circuit schematic of the source line SL_1 shown in FIG. 1 according to an embodiment of the invention.

FIG. 3 illustrates a flow diagram of a manufacturing method of a display panel according to the invention.

FIG. 4 illustrates a flow diagram of a driving method of a display panel according to the invention.

### DESCRIPTION OF THE EMBODIMENTS

The teem “coupled to (or connected to)” used in the entire text of the specification of the present application (including claims) can refer to any direct or indirect connecting means. For instance, if the text describes a first apparatus is coupled to (or connected to) a second apparatus, then it should be understood that the first apparatus can be directly connected to the second apparatus, or the first apparatus can be indirectly connected to the second apparatus via other apparatuses or certain connecting means. Moreover, when applicable, devices/members/steps having the same reference numerals in figures and embodiments represent the same or similar parts. Devices/members/steps having the same reference numerals or having the same terms in different embodiments can be cross-referenced.

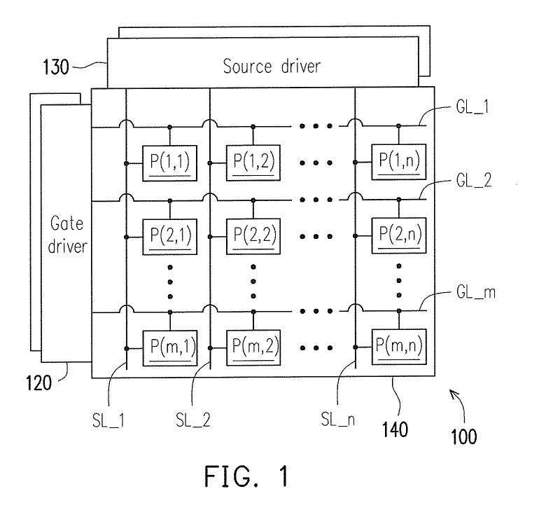

FIG. 1 illustrates circuit block schematic of a display apparatus 100 according to an embodiment of the invention. The display apparatus 100 includes at least one gate drive 120, at least one source driver 130, and one display panel 140. The display panel 140 has two substrates, and a liquid crystal material is filled between the two substrates. The display panel 140 includes a plurality of source lines (or data lines, such as SL_1, SL_2, . . . , and SL_n shown in FIG. 1, wherein n is a positive integer), a plurality of gate lines (or scan lines, such as GL_1, GL_2, . . . , and GL _m shown in FIG. 1, wherein m is a positive integer), and a plurality of pixel circuits (such as P(1,1), P(1,2), . . . , P(1,n), P(2,1), P(2,2), . . . , P(2,n), P(m,1), P(,2), . . . , and P(m,n) shown in FIG. 1). The source lines SL_1 to SL_n are perpendicular to the gate lines GL_1 to GL_m. The pixel units P(1,1) to P(m,n) are distributed on the display panel 140 in a matrix method. The source terminal of each of the pixel circuits P(1,1) to P(m,n) is respectively coupled to the corresponding source lines in the source lines SL_1 to SL_n, and the gate terminal of each of the pixel circuits P(1,1) to P(m,n) is respectively coupled to the corresponding gate lines in the gate lines GL_1˜GL_m, as shown in FIG. 1.

A plurality of output terminals of the gate driver 120 is coupled to different gate lines GL_1 to GL_m in a one-on-one method. The gate driver 120 can drive (or scan) the gate lines of the display panel 140 one by one in turns. For instance, the gate line GL_1 is driven first, and then the gate lines GL_2 to GL_m are driven in order.

The source driver 130 can convert a plurality of digital pixel data into corresponding pixel voltage differences. In accordance with the scan sequence of the gate driver 120, the source driver 130 can write the corresponding pixel voltage differences to the corresponding pixel circuits (such as the pixel circuits P(1,1) to P(m,n) shown in FIG. 1) of the display panel 140 via the source lines SL_1 to SL_n to display an image.

The source lines SL_1 to SL_n generally have impedance (resistive impedance and capacitive impedance). The greater the size of the display panel 140 (longer source lines), the greater the impedance of the source lines SL_1 to SL_n. Moreover, the greater the density/resolution of the display panel 140 (thinner source lines), the greater the impedance of the source lines SL_1 to SL_n.

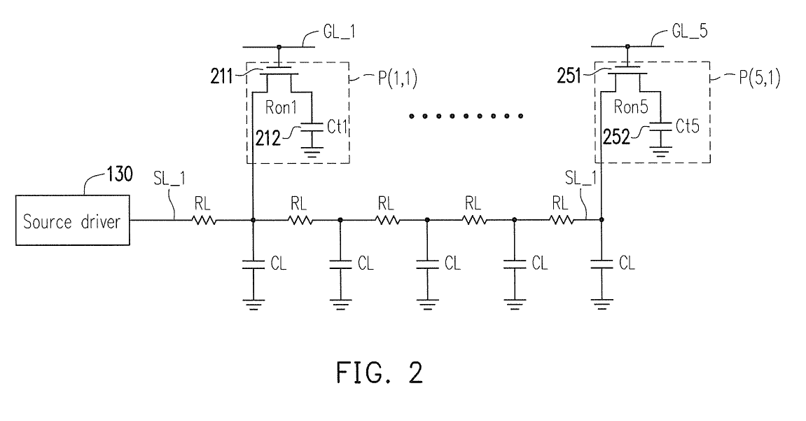

FIG. 2 illustrates an equivalent circuit schematic of the source line SL_1 shown in FIG. 1 according to an embodiment of the invention. For ease of explanation, the number of pixel circuits of the source line SL_1 is set to 5 (i.e., m=5). FIG. 2 illustrates an equivalent circuit diagram of the pixel circuits P(1,1) and P(5,1), and descriptions of the other pixel circuits in the display panel 140 may be deduced by reference with related descriptions for the pixel circuits P(1,1) and P(5,1). On the basis that the distance from the pixel circuit P(1,1) to the source driver 130 is less than the distance from the pixel circuit P(5,1) to the source driver 130, in the following, the pixel circuit P(1,1) is referred to as “near pixel circuit” and the pixel circuit P(5,1) is referred to as “far pixel circuit”. In FIG. 2, a resistance RL and a capacitance CL respectively represent the resistive impedance and the capacitive impedance of the source line SL_1 (metal line). The time constant of the source line SL_1 is close to RL*CL at the near pixel circuit P(1,1). The time constant of the source line SL_1 is close to 15RL*CL at the far pixel circuit P(5,1). In the present embodiment, the input impedance of the source terminal of at least one of the pixel circuits P(1,1) to P(,n) in a turn-on state can be adjusted. For instance, the input impedance of the source terminal of the near pixel circuit P(1,1) in the turn-on state is made greater than the input impedance of the source terminal of the far pixel circuit P(5,1) in the turn-on state to compensate the impedance difference at different locations of the source line SL_1 (i.e., to compensate the time constant difference at different locations of the source line SL_1).

Specifically, the near pixel circuit P(1,1) includes a first transistor 211 and a first capacitor 212. The source of the first transistor 211 is electrically connected to the source line SL_1. The drain of the first transistor 211 is electrically connected to the first capacitor 212. The gate of the first transistor 211 is electrically connected to the first gate line GL_1 of the display panel 140. The far pixel circuit P(5,1) includes a second transistor 251 and a second capacitor 252. The source of the second transistor 251 is electrically connected to the source line SL_1. The drain of the second transistor 251 is electrically connected to the second capacitor 252. The gate of the second transistor 251 is electrically connected to the second gate line GL_5 of the display panel 140. Ron1 in FIG. 2 represents the turn-on resistance of the first transistor 211, Ct1 represents the capacitance value of the first capacitor 212, Ron5 represents the turn-on resistance of the second transistor 251, and Ct5 represents the capacitance value of the second capacitor 252.

In some embodiments, the turn-on resistance Ron2 of the first transistor 211 (i.e., the input impedance of the source terminal of the near pixel circuit P(1,1) in the turn-on state) and the turn-on resistance Ron5 of the second transistor 251 (i.e., the input impedance of the source terminal of the far pixel circuit P(5,1) in the turn-on state) can be adjusted, such that the turn-on resistance Ron1 of the first transistor 211 is greater than the turn-on resistance Ron5 of the second transistor 251. For instance (but not limited to), the width-to-length ratio (such as W1/L1) of the channel of the first transistor 211 and the width-to-length ratio (such as W5/L5) of the channel of the second transistor 251 can be adjusted, such that the width-to-length ratio W1/L1 of the channel of the first transistor 211 is less than the width-to-length ratio W5/L5 of the channel of the second transistor 251. In particular, W1 is the channel width of the first transistor 211, L1 is the channel length of the first transistor 211, W5 is the channel width of the second transistor 251, and L5 is the channel length of the second transistor 251. The width-to-length ratio W1/L1 of the channel of the first transistor 211 is less than the width-to-length ratio W5/L5 of the channel of the second transistor 251. In other words, the turn-on resistance Ron1 of the first transistor 211 is greater than the turn-on resistance Ron5 of the second transistor 251.

In some other embodiments, the gate driver 120 can provide different levels of scanning pulses to the gate lines GL_1 to GL_m, such that the turn-on resistance Ron1 of the first transistor 211 is greater than the turn-on resistance Ron5 of the second transistor 251. For instance (but not limited to), the gate high-voltage (i.e., high-voltage level of scanning pulse) of the gate line GL_1 can be less than the gate high-voltage of the gate line GL_5, such that the turn-on resistance Ron1 of the first transistor 211 is greater than the turn-on resistance Ron5 of the second transistor 251.

In yet some other embodiments, the capacitance value Ct1 of the first capacitor 212 and the capacitance value Ct5 of the second capacitor 252 can be adjusted, such that the capacitance value Ct1 of the first capacitor 212 is greater than the capacitance value Ct5 of the second capacitor 252. For instance (but not limited to), the electrode area (or electrode distance) of the first capacitor 212 and/or the second capacitor 252 can be adjusted to change the capacitance value. The capacitance value Ct1 of the first capacitor 212 is greater than the capacitance value Ct5 of the second capacitor 252, such that the input impedance Z(1,1) of the source terminal of the near pixel circuit P(1,1) in a turn-on state is greater than the input impedance Z(5,1) of the source terminal of the far pixel circuit P(5,1) in the turn-on state.

Under ideal conditions, in the present embodiment, the turn-on resistance Ron1 and/or the capacitance value Ct1 of the near pixel circuit P(1,1) can be adjusted, and/or the turn-on resistance Ron5 and/or the capacitance value Ct5 of the far pixel circuit P(5,1) can be adjusted, such that the time constant RL*CL+Ron1*Ct1 of the near pixel circuit P(1,1) can be close to the time constant 15RL*CL+Ron5*Ct5 of the far pixel circuit P(5,1). Since the impedance difference at different locations of the source line SL_1 is compensated, pixel circuits at different locations of the source line SL_1 have similar time constants. As a result, display abnormality caused by time constant difference (charging time difference) is alleviated.

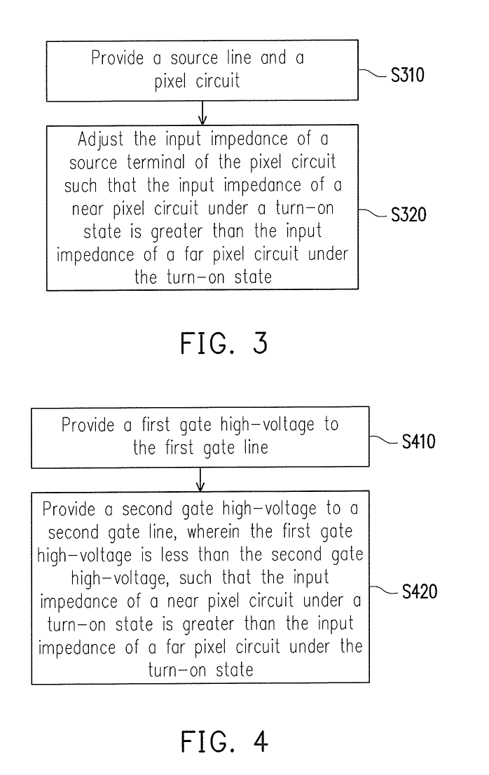

FIG. 3 illustrates a flow diagram of a manufacturing method of a display panel according to the invention. The manufacturing method includes step S310 and step S320. In step 5310, at least one source line and a plurality of pixel circuits are provided to the display panel 140. In particular, the source terminal of each of the pixel circuits is coupled to the source line, such as the source terminal of each of the pixel circuits P(1,1), P(2,1), . . . , and P(m,1) shown in FIG. 1 is coupled to the source line SL_1. The pixel circuits include a near pixel circuit and a far pixel circuit, such that the distance from the near pixel circuit to the source driver 130 is less than the distance from the far pixel circuit to the source driver 130. In step S320, the input impedance of the source terminal of at least one of the pixel circuits is adjusted, such that the input impedance of the source terminal of the near pixel circuit in a turn-on state is greater than the input impedance of the source terminal of the far pixel circuit in the turn-on state.

In some embodiments, the near pixel circuit includes a first transistor and a first capacitor (such as the near pixel circuit P(1,1) shown in FIG. 2 includes the first transistor 211 and the first capacitor 212), and the far pixel circuit includes a second transistor and a second capacitor (such as the far pixel circuit P(5,1) shown in FIG. 2 includes the second transistor 251 and the second capacitor 252). Step S320 shown in FIG. 3 includes: increasing the turn-on resistance of the first transistor, such that the turn-on resistance of the first transistor is greater than the turn-on resistance of the second transistor. For instance, the turn-on resistance Ron1 of the first transistor 211 shown in FIG. 2 is increased, such that the turn-on resistance Ron1 of the first transistor 211 is greater than the turn-on resistance Ron5 of the second transistor 251.

In some embodiments, the step of increasing the turn-on resistance of the first transistor includes: reducing the width-to-length ratio of the channel of the first transistor, such that the width-to-length ratio of the channel of the first transistor is less than the width-to-length ratio of the channel of the second transistor.

In some embodiments, the near pixel circuit includes a first transistor and a first capacitor (such as the near pixel circuit P(1,1) shown in FIG. 2 includes the first transistor 211 and the first capacitor 212), and the far pixel circuit includes a second transistor and a second capacitor (such as the far pixel circuit P(5,1) shown in FIG. 2 includes the second transistor 251 and the second capacitor 252). Step S320 shown in

FIG. 3 includes: increasing the capacitance value of the first capacitor, such that the capacitance value of the first capacitor is greater than the capacitance value of the second capacitor. For instance, the capacitance value Ct1 of the first capacitor 212 shown in FIG. 2 is increased, such that the capacitance value Ct1 of the first capacitor 212 is greater than the capacitance value Ct5 of the second capacitor 252.

FIG. 4 illustrates a flow diagram of a driving method of a display panel according to the invention. The descriptions of the display panel may be deduced by reference with related descriptions for the display panel 140 of FIG. 1 and FIG. 2. The driving method includes step S410 and step S420. In step S410, a first gate high-voltage is provided to the first gate line to turn on the near pixel circuit. For instance, a first gate high-voltage is provided to the gate line GL_1 shown in FIG. 2 to turn on the near pixel circuit P(1,1). In step S420, a second gate high-voltage is provided to the second gate line to turn on the far pixel circuit. For instance, a second gate high-voltage is provided to the gate line GL_5 shown in FIG. 2 to turn on the far pixel circuit P(5,1). In particular, the first gate high-voltage of the first gate line is less than the second gate high-voltage of the second gate line, such that the input impedance of the source terminal of the near pixel circuit in a turn-on state is greater than the input impedance of the source terminal of the far pixel circuit in the turn-on state.

Based on the above, different pixel circuits in the display panel of an embodiment of the invention have different input impedances in a turn-on state. Pixel circuits at different locations have different input impedances, and therefore the impedance difference at different locations of the same source line can be compensated, thus alleviating display abnormality caused by time constant difference (charging time difference).

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A display panel, comprising:
at least one source line; and
a plurality of pixel circuits, wherein a source terminal of each of the pixel circuits is coupled to the source line, the pixel circuits include a near pixel circuit and a far pixel circuit, a distance from the near pixel circuit to a source driver is less than a distance from the far pixel circuit to the source driver, and an input impedance of the source terminal of the near pixel circuit in a turn-on state is greater than an input impedance of the source terminal of the far pixel circuit in the turn-on state.

2. The display panel of claim 1, wherein the near pixel circuit comprises a first transistor and a first capacitor, a source of the first transistor is electrically connected to the source line, a drain of the first transistor is electrically connected to the first capacitor, the far pixel circuit comprises a second transistor and a second capacitor, a source of the second transistor is electrically connected to the source line, and a drain of the second transistor is electrically connected to the second capacitor.

3. The display panel of claim 2, wherein a turn-on resistance of the first transistor is greater than a turn-on resistance of the second transistor.

4. The display panel of claim 2, wherein a width-to-length ratio of a channel of the first transistor is less than a width-to-length ratio of a channel of the second transistor, such that the turn-on resistance of the first transistor is greater than the turn-on resistance of the second transistor.

5. The display panel of claim 2, wherein a gate of the first transistor is electrically connected to a first gate line of the display panel, a gate of the second transistor is electrically connected to a second gate line of the display panel, and a gate high-voltage of the first gate line is less than a gate high-voltage of the second gate line, such that a turn-on resistance of the first transistor is greater than a turn-on resistance of the second transistor.

6. The display panel of claim 2, wherein a capacitance value of the first capacitor is greater than a capacitance value of the second capacitor.

7. A manufacturing method of a display panel, comprising:
providing at least one source line to the display panel;
providing a plurality of pixel circuits to the display panel, wherein a source terminal of each of the pixel circuits is coupled to the source line, the pixel circuits include a near pixel circuit and a far pixel circuit, and a distance from the near pixel circuit to a source driver is less than a distance from the far pixel circuit to the source driver; and
adjusting an input impedance of the source terminal of at least one of the pixel circuits in a turn-on state, such that an input impedance of the source terminal of the near pixel circuit in the turn-on state is greater than an input impedance of the source terminal of the far pixel circuit in the turn-on state.

8. The manufacturing method of claim 7, wherein the near pixel circuit comprises a first transistor and a first capacitor, a source of the first transistor is electrically connected to the source line, a drain of the first transistor is electrically connected to the first capacitor, the far pixel circuit comprises a second transistor and a second capacitor, a source of the second transistor is electrically connected to the source line, and a drain of the second transistor is electrically connected to the second capacitor.

9. The manufacturing method of claim 8, wherein the step of adjusting the input impedance of the source terminal of at least one of the pixel circuits comprises:
increasing the turn-on resistance of the first transistor, such that the turn-on resistance of the first transistor is greater than the turn-on resistance of the second transistor.

10. The manufacturing method of claim 8, wherein the step of increasing the turn-on resistance of the first transistor comprises:
reducing a width-to-length ratio of a channel of the first transistor, such that the width-to-length ratio of the channel of the first transistor is less than a width-to-length ratio of a channel of the second transistor.

11. The manufacturing method of claim 8, wherein the step of adjusting the input impedance of the source terminal of at least one of the pixel circuits comprises:
increasing a capacitance value of the first capacitance, such that the capacitance value of the first capacitance is greater than a capacitance value of the second capacitor.

12. A driving method of a display panel, wherein the display panel comprises at least one source line, a first gate line, a second gate line, and a plurality of pixel circuits, a source terminal of each of the pixel circuits is coupled to the source line, the pixel circuits include a near pixel circuit and a far pixel circuit, a distance from the near pixel circuit to a source driver is less than a distance from the far pixel circuit to the source driver, a gate terminal of the near pixel circuit is electrically connected to the first gate line, a gate terminal of the far pixel circuit is electrically connected to the second gate line, and the driving method comprises:
providing a first gate high-voltage to the first gate line to turn on the near pixel circuit; and
providing a second gate high-voltage to the second gate line to turn on the far pixel circuit, wherein the first gate high-voltage of the first gate line is less than the second gate high-voltage of the second gate line, such that an input impedance of the source terminal of the near pixel circuit in a turn-on state is greater than an input impedance of the source terminal of the far pixel circuit in the turn-on state.
